(19) United States
(12) Patent Application Publication
(10) Pub. No.: US 2017/0186508 A1
(43) Pub. Date: Jun. 29, 2017

(54) METHOD FOR MANUFACTURING GRAPHENE COMPOSITE FILM

(71) Applicant: I-SHOU UNIVERSITY, Kaohsiung (TW)

(72) Inventor: Chiung-Fang LIN, Kaohsiung (TW)

(21) Appl. No.: 14/982,619

(22) Filed: Dec. 29, 2015

(51) Int. Cl. H01B 1/18; C23C 14/06; C23C 14/08; C23C 14/22

(52) U.S. Cl. CPC H01B 1/18; C23C 14/228; C23C 14/0605; C23C 14/081

(57) ABSTRACT

The present invention provides a method for manufacturing a graphene composite film including preparing a zeolite suspension and a graphene oxide suspension containing graphene oxide, reducing the graphene oxide suspension until the graphene oxide is partially reduced to form partially-reduced graphene oxide, followed by adding the zeolite suspension and a surfactant into the partially-reduced graphene oxide suspension to form a composite solution, further reducing the composite solution until the partially-reduced graphene oxide is completely reduced to form graphene, and forming the composite solution into the graphene composite film on a substrate via plasma-enhanced atomizing deposition.

### BACKGROUND OF THE INVENTION

1. Field of the Invention

The present invention generally relates to a method for manufacturing a composite film and, more particularly, to a method for manufacturing a graphene composite film.

2. Description of the Related Art

Graphene is provided with tremendous advantages, such as excellent mechanical properties, high heat conductivity, high electron mobility and high specific area. However, graphene produced via oxidation-reduction method can easily aggregate due to the variation of temperature, pH value or processing steps during such manufacturing processes. Accordingly, the specific area of such graphene is significantly decreased, and the electrical properties of such graphene are also adversely affected, resulting in reduced applicability. On the other hand, graphene dispersed in solution can be easily mixed with selected raw materials to form a composition, which can be utilized to fabricate graphene composite materials with enhanced properties. These composite materials may possess excellent mechanical and electrical properties, and are suitable for further processing, thus providing a variety of applications of such graphene composite materials.

Zeolite is provided with uniformly distributed pores and excellent resistances to heat and compression. Hence, a composite material made of graphene and zeolite mixture, such as a graphene composite film, can be more stable in nature than pure graphene. Besides, with the trimensional structure of zeolite, electron mobility of the graphene composite film can be further increased, which is favorable for redox reaction. Hence, the graphene composite film can be utilized as electric capacity or sensor.

A conventional method for manufacturing a graphene composite film uses graphene produced via oxidation-reduction method. The conventional method includes preparing a graphene oxide suspension and a zeolite suspension, reducing the graphene oxide suspension to form a graphene suspension, and mixing the graphene suspension with the zeolite suspension. Next, the mixture of the graphene suspension and the zeolite suspension is applied on a substrate by spin coating, and is calcinated under a high temperature for several hours to form the graphene composite film.

However, since the graphene used in the conventional method is produced through oxidation-reduction method, the graphene usually has more than ten layers, which is thick and tends to have defects. Besides, since the graphene composite film is formed from the mixture containing such graphene via spin coating, the graphene composite is provided with poor electrical properties, uneven thickness, rough surface and weak adhesion with the substrate, adversely affecting its applicability.

### SUMMARY OF THE INVENTION

It is therefore the objective of this invention to overcome the above problems, providing a method for manufacturing a graphene composite film with improved electrical properties, uniform thickness and smooth surface.

The present invention provides a method for manufacturing a graphene composite film including preparing a zeolite suspension containing zeolite nanocrystals with a concentration of 50-100 ppm and a graphene suspension containing graphene oxide with a concentration of 50-200 ppm; reducing the graphene suspension until the graphene oxide is partially reduced to form partially-reduced graphene oxide; mixing the reduced graphene suspension with the zeolite suspension according to a volume ratio of 1:1 to 9:1, and adding a surfactant to the mixture to form a composite solution; reducing the composite solution until the partially-reduced graphene oxide is completely reduced to form graphene; atomizing the reduced composite solution to form atomized droplets; treating the atomized droplets with a plasma to charge the atomized droplets; and depositing the charged atomized droplets on a substrate. A particle size of the zeolite nanocrystals is 50-80 nm. A temperature of the substrate is 150-350° C. As such, the graphene composite film can be manufactured.

In a form shown, reducing the graphene suspension includes adding an alkali into the graphene suspension and sonicating the graphene suspension containing the alkali under a temperature of 50-90° C. As such, defects of the partially-reduced graphene oxide can be prevented.

In the form shown, reducing the composite solution includes sonicating the composite solution containing the alkali under a temperature of 50-90° C. As such, defects of the partially-reduced graphene oxide can be prevented.

In the form shown, the alkali is lithium hydroxide, sodium hydroxide, potassium hydroxide or calcium hydroxide. The alkali is not harmful to the environment.

In the form shown, the surfactant is 1-methy-2-pyrrolidone, isopropanol (NMP), propylene glycol methyl ether (PGME), ethyl acetate or methyl ethyl ketone (MEK). As such, the graphene is provided with fewer layers.

In the form shown, the zeolite suspension further comprises a metal salt. As such, the specific capacity of the graphene composite film can be improved.

In the form shown, the metal salt is a salt of gold, platinum, silver, copper or nickel. As such, the specific capacity of the graphene composite film can be improved.

In the form shown, mixing the reduced graphene suspension with the zeolite suspension includes sonicating the mixture of the reduced graphene suspension and the zeolite suspension for 2-5 hours before adding the surfactant. As such, the graphene is provided with fewer layers.

In the form shown, treating the atomized droplets with the plasma includes using a gas to carry the atomized droplets through the plasma. As such, the adhesion of the graphene composite film with the substrate is enhanced.

In the form shown, the gas is argon, helium or a mixed gas comprising argon and hydrogen. As such, the graphene is prevented from being oxidized again.

According to the method for manufacturing the graphene composite film of the present disclosure, the zeolite nanocrystals is added to the graphene suspension when the graphene oxide is partially reduced to form the partially-reduced graphene oxide, and the partially-reduced graphene oxide is then completely reduced. Thus, the graphene of the graphene composite film is provided with fewer layers and fewer defects, improving the electrical properties of the graphene.

Besides, in the method of the present disclosure, since the graphene composite film is formed from the composite solution via plasma-enhanced atomizing deposition, the graphene surrounds the zeolite. Consequently, the zeolite nanocrystals and the graphene can jointly form the graphene composite film with smooth surface and uniform thickness, improving the applicability of the graphene composite film.

Moreover, in the method of the present disclosure, since the metal salt is added to the zeolite suspension, the metal ion can be introduced into the zeolite nanocrystals, thus increasing the specific capacity of the graphene composite film.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1a is a 1,000×SEM image of the graphene composite film of Group B1.

FIG. 1b is a 100,000×SEM image of the graphene composite film of Group B1.

FIG. 1c is a cross sectional SEM image of the graphene composite film of Group B1.

FIG. 2a is a 1,000×SEM image of the graphene composite film of Group B2.

FIG. 2b is a 50,000×SEM image of the graphene composite film of Group B2.

FIG. 2c is a cross sectional SEM image of the graphene composite film of Group B2.

FIG. 3a is a FT-IR spectrum of graphene oxide.

FIG. 3b is a FT-IR spectrum of graphene.

FIG. 3c is a FT-IR spectrum of zeolite.

FIG. 3d is a FT-IR spectrum of the graphene composite film of the present disclosure.

FIG. 4 is the cyclic voltammetry results of Group D1 and Group D5.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

The present invention provides a method for manufacturing a graphene composite film including preparing a zeolite suspension and a graphene suspension containing graphene oxide, reducing the graphene suspension until the graphene oxide is partially reduced to form partially-reduced graphene oxide, followed by adding the zeolite suspension and a surfactant into the reduced graphene suspension to form a composite solution, further reducing the composite solution until the partially-reduced graphene oxide is completely reduced to form graphene, and forming the composite solution into the graphene composite film on a substrate via plasma-enhanced atomizing deposition.

Specifically, the zeolite suspension contains zeolite nanocrystals with the particle size of 50-80 nm, and the concentration of the zeolite suspension is 50-100 ppm. The zeolite suspension can be prepared through any known method in the art, and the pH value of the zeolite suspension can be 11-13. For example, the zeolite nanocrystals can be aluminosilicate zeolite, and can have a chemical formula of M_{x/n}[(AlO₂)ₓ(SiO₂)_{y}]·mH₂O, with x≦y. In this chemical formula, n indicates the oxidation number of the cation M. The cation M is, but not limited to, alkali metal, alkaline earth, rare earth, ammonia or hydrogen ion.

In this embodiment, the zeolite suspension is prepared by mixing 16.04 g tetramethylammonium hydroxide (TMAOH) with 25.35 g pure water, followed by adding 3.835 g aluminum isopropoxide and 6.009 g silicon dioxide and stirring for 24 hours. Next, the reaction mixture is placed in a sealed container and reacts for 48 hours under 92° C. The reacted product is centrifuged under a low speed (e.g. 3000 rpm, 30 min) for removing large particles precipitated, and is further centrifuged under a high speed (e.g. 12000 rpm, 30 min) to remove small particles in the supernatant. About 20 ml of such zeolite suspension is thus obtained with its pH value being about 11.

Furthermore, with the ion-exchange capacity of zeolite, metal ions having high electric conductivity can be introduced into the zeolite nanocrystals, such that the specific capacity of the graphene composite film can be improved. For instance, the metal ion can be selected from gold ion, platinum ion, silver ion, copper ion and nickel ion, which can be readily appreciated by persons ordinarily skilled in the art. As an example, the zeolite suspension can further includes a metal salt, such that the metal ion of the metal salt can enter the zeolite nanocrystals. In this embodiment, 1 M aqueous solution of silver nitrate is added to the zeolite suspension to reach a weight ratio of 0.3%. The zeolite suspension containing silver nitrate is placed in a sealed plastic container and sonicated (e.g. with ultrasound) for 8 hours under 80° C. in dark place. Finally, the pH value of the zeolite suspension containing silver nitrate is adjusted to 11 using ammonium solution.

The graphene suspension includes the graphene oxide with a concentration of 50-200 ppm, and can be prepared through any known method in the art, such as mixing a carbon source material (e.g. graphite) with an oxidant, and then filtering and washing the oxidized carbon material. In this embodiment, 0.2 g flake graphite is mixed with 12 ml concentrated sulfuric acid by stirring 1 hour in ice bath. And then, 2 g potassium permanganate is added, and the reaction mixture is stirred for one more hour. Next, the reaction mixture is stirred for one hour under 40° C. before adding 25 ml pure water. After adding pure water, the reaction mixture is transferred to 95-98° C. and stirred for 15 min, followed by adding hydrogen peroxide until there is no bubble generated in the reaction mixture. The reaction mixture is then centrifuged (12000 rpm, 15 min) before cooling down, and is washed until reach a pH value of 4. Finally, the reaction mixture is further sonicated (e.g. with ultrasound) until there is no apparent particle, thus forming the graphene suspension.

After that, the graphene oxide is partially reduced to form the partially-reduced graphene oxide. Namely, each graphene oxide particle is partially reduced, such as being reduced on the plane, with the peripheral area thereof still being oxidized. The term “partially-reduced graphene oxide” indicates a state between the graphene oxide and the graphene (or so called reduced graphene oxide). Specifically, a reducing gas is conducted in the graphene suspension to conduct the reduction reaction. Alternatively, a reductant is added in the graphene suspension, with the reductant being selected from any well-known reductant that is suitable for reducing graphene oxide. Besides, the reductant can be a basic compound, such as hydrazine, which will significantly change the pH value of the graphene suspension or the zeolite suspension. Alternatively, the graphene suspension can be mixed with an alkali and sonicated for reducing the graphene oxide. For instance, the alkali can be lithium hydroxide, sodium hydroxide, potassium hydroxide or calcium hydroxide, for providing reductive environment. Toxicity of these alkalis is lower than hydrazine, and the use of these alkalis is beneficial for controlling reduction rate. In this embodiment, 20 ml aqueous solution of sodium hydroxide (4M) is added to 200 ml of the graphene suspension. The graphene suspension containing sodium hydroxide is then sonicated under 50° C., until the color of the graphene suspension turns from bight yellow to brown.

When the graphene oxide is partially reduced to form the partially-reduced graphene oxide, the zeolite suspension is added to the reduced graphene suspension immediately. Since graphene appears to be brownish-yellow in oxidized state and is black when completely reduced, one in the art would appreciate that when the color of the graphene suspension turns from brownish-yellow to deep brown, the partially-reduced graphene oxide is readily formed. Specifically, the color of the graphene suspension may turns from PANTONE 124 to PANTONE 1405. Besides, since the partially-reduced graphene oxide is still provided with excellent dispersive ability, the reduced graphene suspension should not be precipitated after 15 minutes centrifugation under 10000 rpm.

The reduced graphene suspension is mixed with the zeolite suspension according to a volume ratio of 1:1 to 9:1. And then, the surfactant is added to the mixture of the reduced graphene suspension and the zeolite suspension to form the composite solution. In the case that the alkali exists in the graphene suspension, the reduced graphene suspension can be kept under 15° C. before mixing with the zeolite suspension and the surfactant for temporarily stopping the reduction reaction. For instance, when the color of the graphene suspension turns to deep brown, the graphene suspension is transferred into a water bath at 15° C. immediately. Moreover, the mixture of the reduced graphene suspension and the zeolite suspension can be sonicated for 2-5 hours before adding the surfactant. The surfactant can be any surfactant suitable for producing graphene via oxidation-reduction method, such as 1-methy-2-pyrrolidone (NMP), isopropanol, propylene glycol methyl ether (PGME), ethyl acetate or methyl ethyl ketone (MEK).

Then, the composite solution is further reduced until the partially-reduced graphene oxide is completely reduced to form the graphene. For instance, the reducing gas can be conducted to the composite solution again, or the reductant or the alkali can be added. Alternatively, in the case that the reductant or the alkali has already existed in the composite solution, the reduction reaction can be carried out again by simply sonicating (e.g. with ultrasound) the composite solution for 8-24 hours. Since the composite solution already contains the zeolite nanocrystals with its size approximating the size of the graphene, the graphene can be prevented from aggregation during reduction reaction. Furthermore, by using the surfactant and ultrasonic treatment, the graphene is provided with less than five layers, thus improving electrical properties of the graphene. In this embodiment, the reduced graphene suspension containing sodium hydroxide described above is mixed with the zeolite suspension, and the mixture is sonicated for 3 hours before adding NMP. After adding NMP, the composite solution is sonicated at 80° C. for 24 hours, so as to assure that the graphene is completely reduced.

After the graphene is completely reduced, the composite solution is deposited on the substrate to from the graphene composite film via plasma-enhanced atomizing deposition. Specifically, the composite solution is atomized to form atomized droplets via an atomizer, such as an ultrasonic oscillator or the like, as would be appreciated by persons ordinarily skilled in the art. At the time the atomized droplets are formed, the graphene surrounds the zeolite nanocrystals to form a structure similar to a graphene ball.

The atomized droplets are treated by a plasma, and then are deposited on the substrate. For instance, the atomized droplets are carried by an inert gas (e.g. argon or helium) or a mixed gas (e.g. Ar/H₂ mixture) through the plasma and deposited on the substrate, with the temperature of the substrate being 150-350° C. Through plasma treatment, the zeolite nanocrystals can be activated, forming strong intertwined state with the graphene. Thus, adhesion between the graphene composite film and the substrate can be further enhanced. In this embodiment, the temperature of the substrate is 230° C. An atmospheric plasma system is used to generate the plasma by applying a voltage of 60-90 V. Alternatively, a pulsed AC voltage can be used. Besides, in this embodiment, argon is used to carry the atomized droplets, and the flow rate of argon is set at 6-10 L/m. Meanwhile, the flow rate of the atomized droplets is about 60-100 ml/min. These factors can be adjusted according to requirements of the graphene composite film, such as the desired thickness of the graphene composite film, which is not limited in the present disclosure.

According to the above, by using the method for manufacturing the graphene composite film, the graphene surrounds the zeolite nanocrystals, and then the graphene and the zeolite nanocrystals jointly form the graphene composite film with smooth surface. Besides, the graphene is provided with fewer layers and fewer defects, thus having improved electrical properties. Consequently, the graphene composite film is provided with a lot of advantages, such as enhanced adhesion with the substrate, smooth surface and improved electrical properties.

To validate that the method of the present disclosure can readily manufacture the graphene composite having characteristics of both the zeolite nanocrystals and the graphene, and provided with smooth surface and excellent electrical properties, the following experiments are carried out.

(A) Comparison of Graphene Quality

The experiment is carried out to prove that the graphene composite film manufactured according to the present disclosure is provided with fewer layers and fewer defects. The zeolite suspension and the graphene suspension are initially prepared according to the above disclosure. In Group A1, the zeolite suspension and the surfactant are added to the graphene suspension when the graphene oxide is reduced to form the partially-reduced graphene oxide. And then, the partially-reduced graphene oxide is completely reduced to form the graphene. On the other hand, in Group A2, the zeolite suspension and the surfactant are mixed with the graphene suspension after the graphene oxide is completely reduced into the graphene. Light transmittances of Group A1 and Group A2 are detected and recorded as shown in Table 1 below.

TABLE 1
Transmittance of Group A1 and Group A2

| Sample | Transmittance (%) |
|---|---|
| Group A1 | 86 |
| Group A2 | 65 |

Since the light transmittance of graphene correlates to its layer number and defect amount, the higher the transmittance, the fewer the layer number and defect amount. According to Table 1, since the zeolite is added when the graphene oxide is reduced to the partial-reduce graphene, and then the reduction reaction is continued, the graphene of Group A1 can thus be formed with fewer layers and fewer defects. In contrast, since the zeolite suspension in Group A2 is added after the graphene is already completely reduced, the graphene is provided with lower transmittance, indicating much more layers and serious defects.

(B) Comparison of Morphology of Graphene Composite Film

The graphene suspension and the zeolite suspension are prepared as described above and are mixed together according to the volume ratio of 7:3. After 3 hours of ultrasonic treatment, NMP is added and the partially-reduced graphene oxide is then completely reduced to form the graphene. The composite solution is obtained, and is further used to manufacture the graphene composite film of Group B1 via plasma-enhanced atomizing deposition. Another graphene composite film is manufactured using the same composite solution but using spin coating for comparison, which is taken as Group B2.

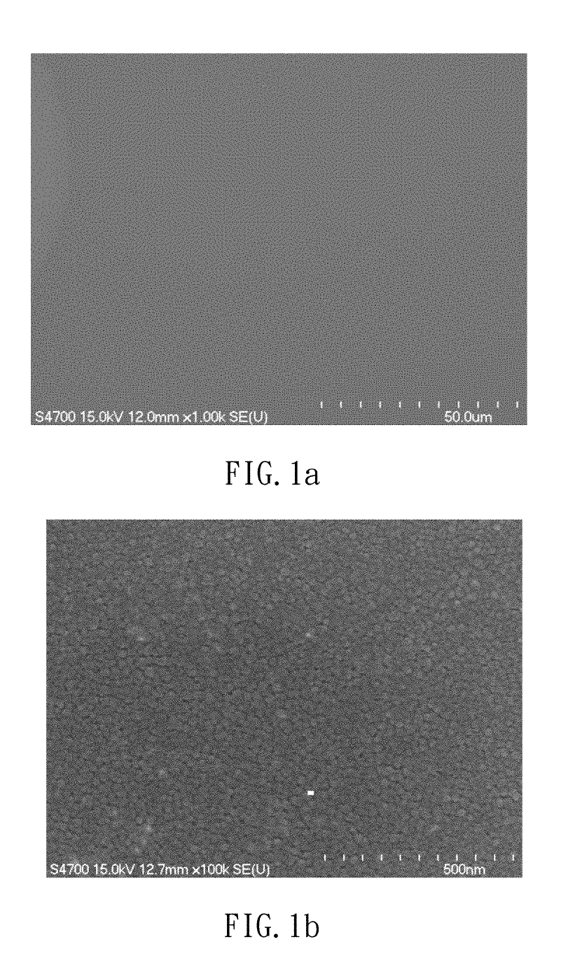

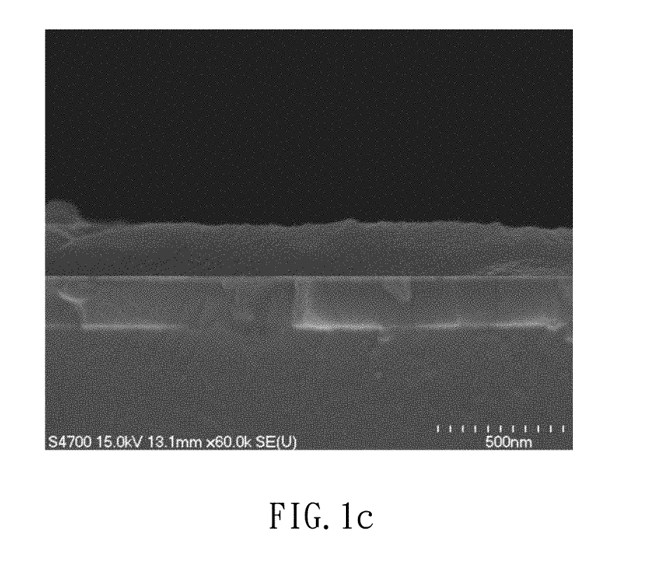

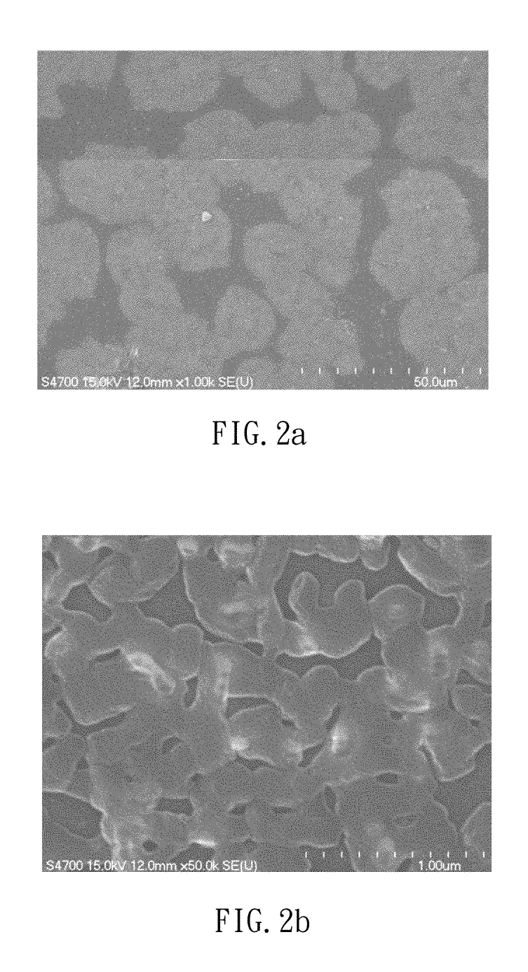

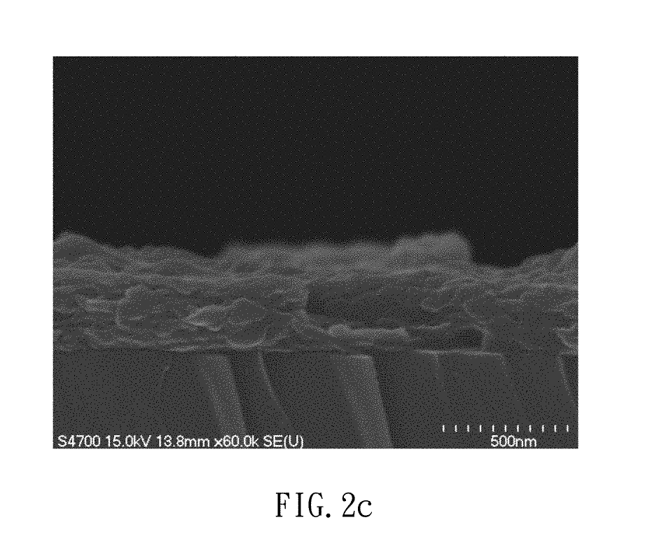

Please refer to FIGS. 1a and 1b, which are the 1,000× and 100,000×SEM images of the graphene composite film of Group B1. FIG. 1c is the cross sectional SEM image of the graphene composite film of Group B1. In addition, FIGS. 2a and 2b are the 1,000× and 50,000×SEM images of the graphene composite film of Group B2, and FIG. 2c is the cross sectional SEM image of the graphene composite film of Group B2. According to these images, the graphene composite film manufactured according to the present disclosure is provided with smooth surface. Besides, uniformly distributed particles can be seen in the magnified image, indicating that the graphene and the zeolite nanocrystals are combined together to form the graphene composite film. In contrast, the graphene composite film manufactured via spin coating shows significant aggregation, with rough surface and uneven thickness.

(C) Analysis of Chemical Properties and Composition of the Graphene Composite Film

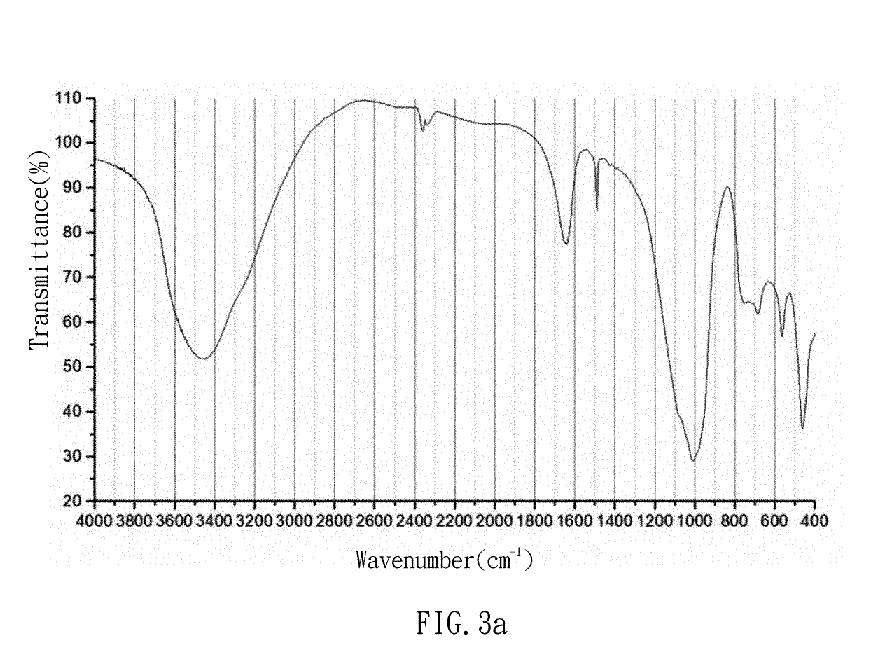

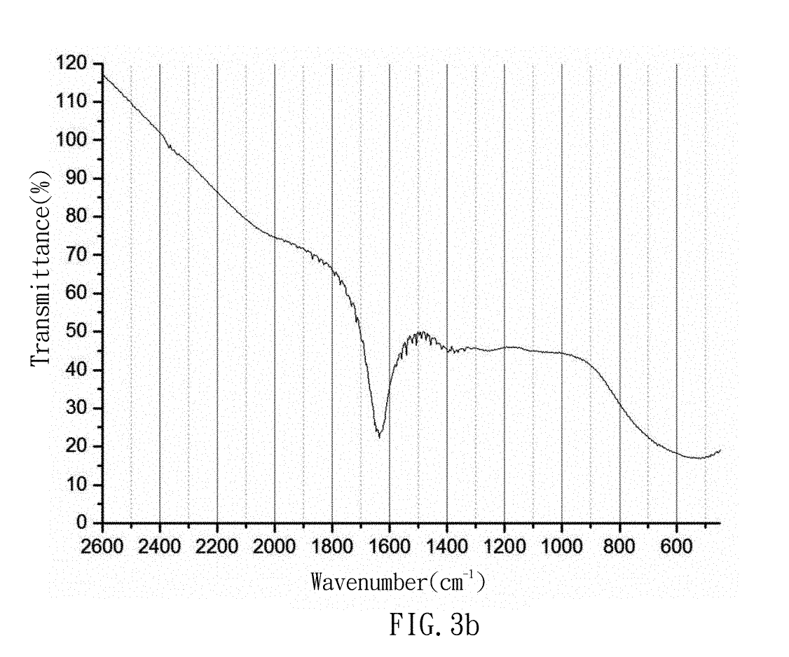

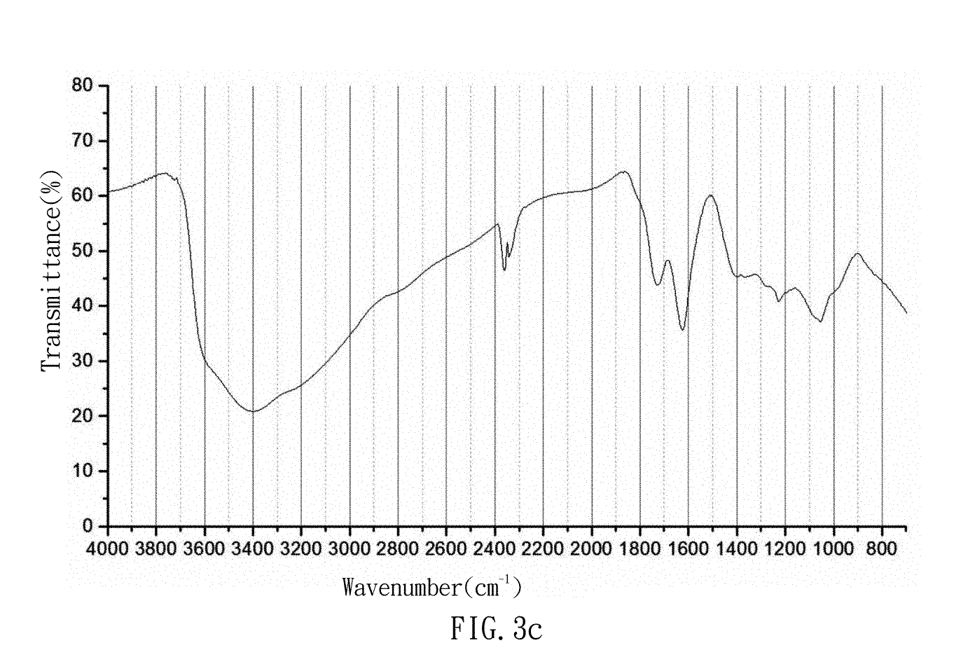

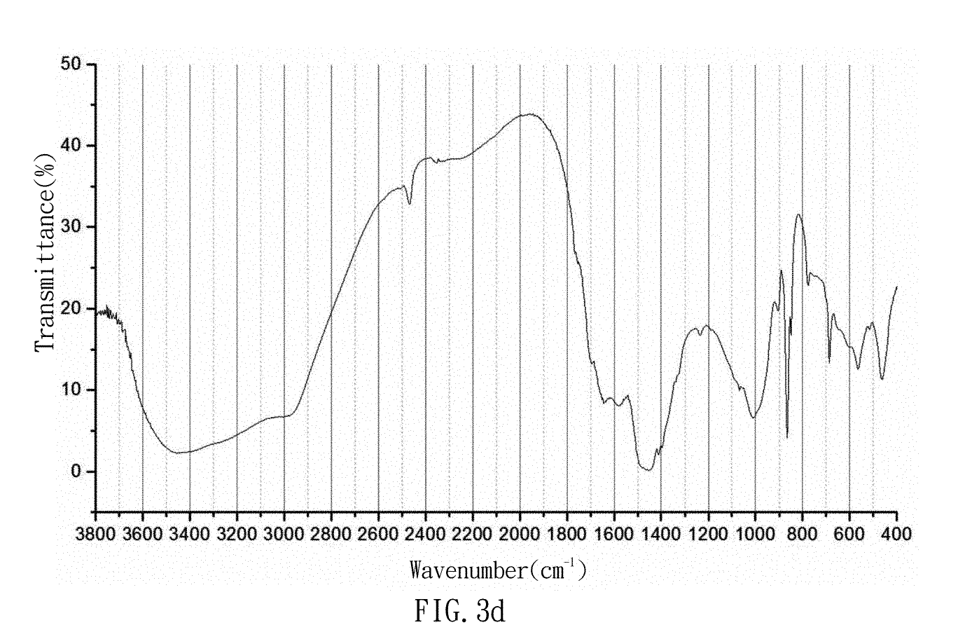

The graphene suspension containing graphene oxide as described above is taken as Group C1. In Group 2, the graphene suspension described above is reduced until the graphene oxide is completely reduced to graphene, which represents pure graphene. The zeolite suspension described above is taken as Group C3, and the composite solution of Group B1 described above is taken as Group C4. Thin films of Group C1 to Group C4 are manufactured via plasma-enhanced atomizing deposition, and the FT-IR spectrums of them are shown as FIGS. 3a-3d. With references to FIGS. 3a and 3b (Group C1 and C2), it can be seen that the peak at 1414 cm⁻¹ disappears when the graphene oxide is completely reduced to graphene. Referring to FIG. 3d (Group C4), when comparing with FIGS. 3a-3d, it is clear that the graphene composite film possess the characteristics of graphene (the peaks at 1620-1680 cm⁻¹) and the characteristics of zeolite (the peaks at 500-700 cm⁻¹). Besides, the graphene contained in the graphene composite film is completely reduced.

The graphene composite film is further analyzed using EDS, showing the ratio of C/Si at about 2.2, which matches with the volume ratio of the graphene suspension and the zeolite suspension. Hence, it can be appreciated that the graphene and the zeolite nanocrystals are combined together according to such volume ratio, forming the graphene composite film with uniformly distributed graphene and zeolite nanocrystals.

(D) Analysis of Electrical Properties of the Graphene Composite Film

Pure graphene (same as Group C2) is taken as Group D1, and the zeolite suspension (same as Group C3) is taken as Group D2. Besides, the zeolite suspension containing silver ion introduced as described above is taken as Group D3. The composite solution containing the graphene and the zeolite nanocrystals (same as Group C4) is taken as Group D4, and the composite solution containing the graphene and the zeolite nanocrystals having silver ion introduced is taken as Group D5. Thin films of Group D1 to Group D5 are manufactured via plasma-enhanced atomizing deposition, and specific capacity with or without electrolyte (1 M sodium hydroxide aqueous solution) of them are detected and recorded in Table 2 below.

TABLE 2
Specific Capacity of Group D1 to Group D5

| | Specific Capacity without | Specific Capacity with |
|---|---|---|
| Sample | Electrolyte (F/g) | Electrolyte (F/g) |
| Group D1 | 10⁻² | 145 |
| Group D2 | 1.3 × 10⁻⁶ | 5.2 |
| Group D3 | 9.3 × 10⁻⁶ | 25 |
| Group D4 | 10⁻² | 120 |
| Group D5 | 3 × 10⁻² | 185 |

According to the results shown above, the specific capacity of the graphene composite film (Group D4) approximates that of pure, completely reduced graphene (Group D1). The specific capacity of the zeolite nanocrystals having silver ion introduced (Group D3) approximates that of the pure zeolite nanocrystals (Group D3). In addition, the graphene composite film manufactured with the zeolite nanocrystals having silver ion introduced (Group D5) can further improve the electrical properties of the graphene composite film, thus having the specific capacity greater than that of the graphene composite film without silver ion introduced (Group D4).

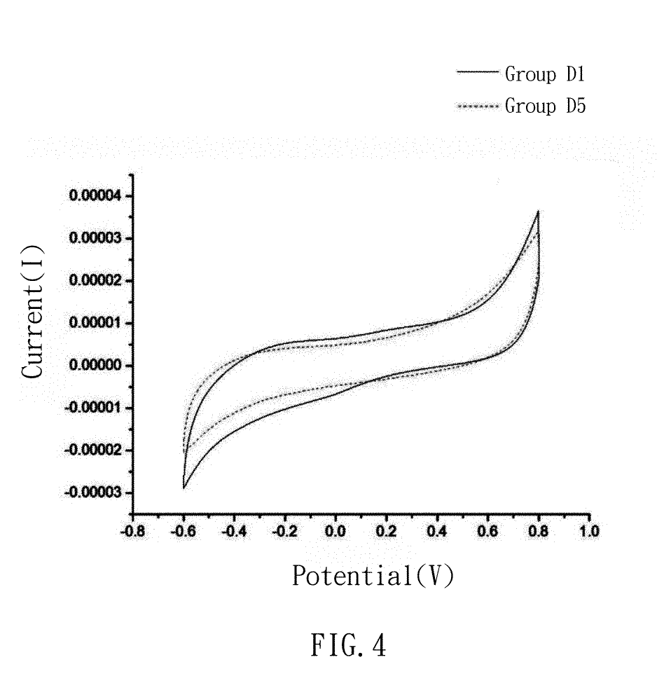

The films of Group D1 and Group D5 are further analyzed via cyclic voltammetry, and the results are provided in FIG. 4. Within the range of −0.6 to −0.2 V, it can be seen that the current variation of the graphene composite film of the present disclosure (Group D5) is more stable than that of the pure graphene (Group D1).

In light of the above, according to the method for manufacturing the graphene composite film of the present disclosure, the zeolite nanocrystals is added to the graphene suspension when the graphene oxide is partially reduced to form the partially-reduced graphene oxide, and the partially-reduced graphene oxide is then completely reduced. Thus, the graphene of the graphene composite film is provided with fewer layers and fewer defects, improving the electrical properties of the graphene.

Besides, in the method of the present disclosure, since the graphene composite film is formed from the composite solution via plasma-enhanced atomizing deposition, the graphene surrounds the zeolite. Consequently, the zeolite nanocrystals and the graphene can jointly form the graphene composite film with smooth surface and uniform thickness, improving the applicability of the graphene composite film.

Moreover, in the method of the present disclosure, since the metal salt is added to the zeolite suspension, the metal ion can be introduced into the zeolite nanocrystals, thus increasing the specific capacity of the graphene composite film.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A method for manufacturing a graphene composite film, comprising:
preparing a zeolite suspension containing zeolite nanocrystals with a concentration of 50-100 ppm, wherein a particle size of the zeolite nanocrystals is 50-80 nm;
preparing a graphene oxide suspension containing graphene oxide with a concentration of 50-200 ppm;
reducing the graphene oxide suspension until the graphene oxide is partially reduced to form partially-reduced graphene oxide, obtaining a partially-reduced graphene oxide suspension being a suspension of the partially-reduced graphene oxide;
mixing the partially-reduced graphene oxide suspension with the zeolite suspension according to a volume ratio of 1:1 to 9:1, and adding a surfactant to the mixture to form a composite solution, wherein the surfactant is either propylene glycol methyl ether (PGME) or ethyl acetate;
reducing the composite solution until the partially-reduced graphene oxide is completely reduced to form graphene;
atomizing the reduced composite solution to form atomized droplets;
treating the atomized droplets with a plasma to charge the atomized droplets; and
depositing the charged atomized droplets on a substrate, wherein a temperature of the substrate is 150-350° C.

2. The method for manufacturing the graphene composite film as claimed in claim 1, wherein reducing the graphene oxide suspension comprises adding an alkali into the graphene oxide suspension and sonicating the graphene oxide suspension containing the alkali under a temperature of 50-90° C.

3. The method for manufacturing the graphene composite film as claimed in claim 2, wherein reducing the composite solution comprises sonicating the composite solution containing the alkali under a temperature of 50-90° C.

4. The method for manufacturing the graphene composite film as claimed in claim 2, wherein the alkali is lithium hydroxide, sodium hydroxide, potassium hydroxide or calcium hydroxide.

5. (canceled)

6. The method for manufacturing the graphene composite film as claimed in claim 1, wherein the zeolite suspension further comprises a metal salt.

7. The method for manufacturing the graphene composite film as claimed in claim 6, wherein the metal salt is a salt of gold, platinum, silver, copper or nickel.

8. The method for manufacturing the graphene composite film as claimed in claim 1, wherein mixing the partially-reduced graphene oxide suspension with the zeolite suspension comprises sonicating the mixture of the partially-reduced graphene oxide suspension and the zeolite suspension for 2-5 hours before adding the surfactant.

9. The method for manufacturing the graphene composite film as claimed in claim 1, wherein treating the atomized droplets with the plasma comprises using a gas to carry the atomized droplets through the plasma.

10. The method for manufacturing the graphene composite film as claimed in claim 9, wherein the gas is argon, helium or a mixed gas comprising argon and hydrogen.
